(19) United States
(12) Patent Application Publication
(10) Pub. No.: US 2026/0082954 A1
(43) Pub. Date: Mar. 19, 2026

(54) ISOLATOR

(71) Applicants: Kabushiki Kaisha Toshiba, Tokyo (JP); Toshiba Electronic Devices & Storage Corporation, Tokyo (JP)

(72) Inventors: Yuusuke IMAIZUMI, Kawasaki Kanagawa (JP); Daijo CHIDA, Kawasaki Kanagawa (JP); Hitoshi IMAI, Kawasaki Kanagawa (JP); Daisuke KOIKE, Tama Tokyo (JP); Shiro OKADA, Suginami Tokyo (JP)

(21) Appl. No.: 19/060,452

(22) Filed: Feb. 21, 2025

(30) Foreign Application Priority Data
Sep. 17, 2024 (JP) 2024-160192

(51) Int. Cl. H01L 23/538; H01L 23/31; H01L 23/498; H01L 25/07

(52) U.S. Cl. CPC H10W 70/65; H10W 70/611; H10W 70/685; H10W 90/00; H10W 70/688; H10W 74/111; H10W 90/22; H10W 90/293; H10W 90/701; H10W 90/724

(57) ABSTRACT

An isolator includes a substrate, a first chip, and a second chip. The substrate includes an insulation layer and a pair of coils. The pair of coils are opposite to each other in a thickness direction via the insulation layer. The first chip is disposed to face one surface of the substrate. The first chip is connected to one of the pair of coils. The second chip is disposed to face the other surface of the substrate. The second chip is connected to the other of the pair of coils.

### CROSS-REFERENCE TO RELATED APPLICATION

This application is based upon and claims the benefit of priority from Japanese Patent Application No. 2024-160192, filed on Sep. 17, 2024, the entire contents of which are incorporated herein by reference.

### FIELD

Embodiments described herein relate to an isolator.

### BACKGROUND

Isolators which transmit a signal from a transmission-side circuit to a reception-side circuit while insulating the transmission-side circuit from the reception-side circuit are known.

### BRIEF DESCRIPTION OF THE DRAWINGS

FIG. 1 is a plan view of an isolator in an embodiment.

FIG. 2 is a cross-sectional view of an isolator package relating to an isolator in the embodiment.

FIG. 3 is a perspective view of a substrate relating to an isolator in an embodiment.

FIG. 4 is a perspective view of a substrate relating to an isolator in an embodiment.

FIG. 5 is a cross-sectional view of a substrate relating to an isolator in an embodiment.

FIG. 6 is a cross-sectional view of a substrate relating to an isolator in a modified example.

### DETAILED DESCRIPTION

An isolator in an embodiment includes a substrate, a first chip, and a second chip. The substrate includes an insulation layer and a pair of coils. The pair of coils are opposite to each other in a thickness direction via the insulation layer. The first chip is disposed to face one surface of the substrate. The first chip is connected to one of the pair of coils. The second chip is disposed to face the other surface of the substrate portion. The second chip is connected to the other of the pair of coils.

An isolator in an embodiment will be described below with reference to the drawings.

### First Embodiment

A constitution of an isolator 10 in a first embodiment will be described below.

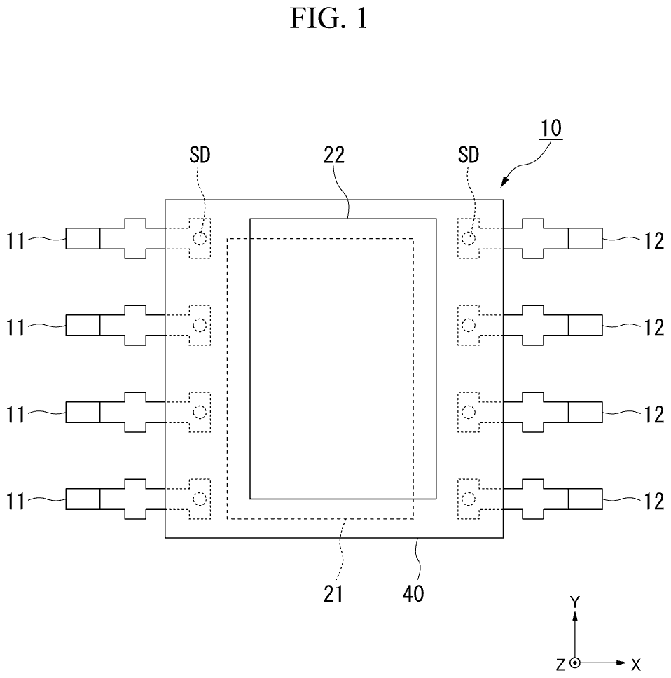

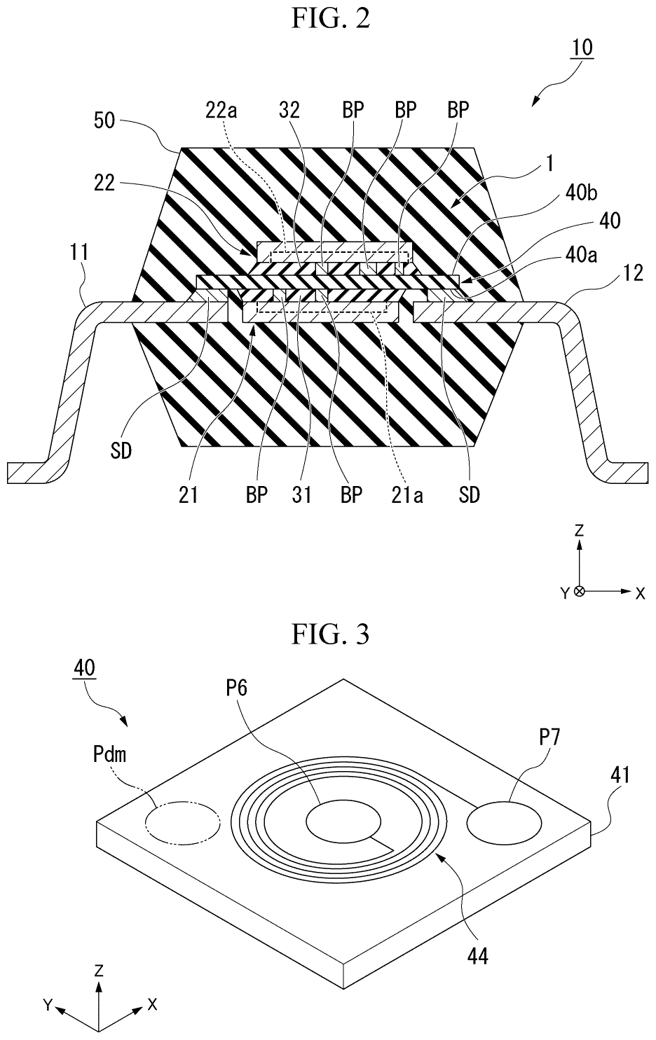

FIG. 1 is a plan view showing an example of a planar layout of the isolator 10 according to the embodiment. FIG. 2 is a cross-sectional view of an isolator package 1 according to the embodiment.

As shown in FIG. 2, the isolator package 1 has the isolator 10 and a package member 50. The package member 50 is made of, for example, an insulating resin material. The package member 50 seals the isolator 10 to protect the isolator 10 from the outside.

The isolator 10 is a so-called digital isolator. The isolator 10 includes a plurality of first terminals 11, a plurality of second terminals 12, a first semiconductor chip (first chip) 21, a second semiconductor chip (second chip) 22, and a substrate 40.

The substrate 40 has a plate shape. The substrate 40 is a module which functions as a digital isolator. The substrate 40 has a transformer installed therein. The substrate 40 is configured to transmit a signal using the transformer while insulating a transmission-side circuit (primary circuit) from a reception-side circuit (secondary circuit). The constitution of the substrate 40 will be described in detail below.

Hereinafter, a plane parallel to a plane of the substrate 40 is referred to as an XY plane. Directions which intersect perpendicularly to each other in the XY plane are defined as an X-axis direction and a Y-axis direction. Particular, in the isolator 10, a direction in which the terminals 11 and 12 extend is defined as the X-axis direction. Furthermore, a direction which intersects the XY plane is defined as a Z-axis direction. The Z-axis direction coincides with a thickness direction of the substrate 40. In addition, the Z-axis direction also coincides with the thickness direction of the first semiconductor chip 21, the second semiconductor chip 22, and the substrate 40.

In the following description, a side on which the second semiconductor chip 22 is disposed with respect to the substrate 40 is referred to as an upper side (+Z) and the opposite side on which the first semiconductor chip 21 is disposed with respect to the substrate 40 is referred to as a lower side (−Z). A posture of the isolator package 1 at the time of using the isolator package 1 is not limited to the upward/downward direction described above.

The substrate 40 has an upper surface 40b facing the upper side (+Z) and a lower surface 40a facing the lower side (−Z). The second semiconductor chip 22 is fixed to the upper surface 40b of the substrate 40 via an insulating adhesive 32. The first semiconductor chip 21 is fixed to the lower surface 40a of the substrate 40 via an insulating adhesive 31. The insulating adhesives 31 and 32 temporarily fix the first semiconductor chip 21 and the second semiconductor chip 22 to the substrate 40 until the isolator 10 is encapsulated using the package member 50 and the isolator 10 is fixed in a production step.

The substrate 40 is electrically connected to the first semiconductor chip 21 and the second semiconductor chip 22 via bumps BP. The substrate 40, the first semiconductor chip 21, and the second semiconductor chip 22 are connected through, for example, flip chip bonding. The bumps BP are formed through, for example, soldering.

As shown in FIG. 1, the first semiconductor chip 21 and the second semiconductor chip 22 overlap each other when viewed in the thickness direction (Z-axis direction) of the substrate 40. The substrate 40 is disposed between the first semiconductor chip 21 and the second semiconductor chip 22.

As shown in FIG. 2, the plurality of first terminals 11 and the plurality of second terminals 12 are connected to the lower surface 40a of the substrate 40 via solder portions SD. Thus, the substrate 40 is electrically connected to the plurality of first terminals 11 and the plurality of second terminals 12.

The first semiconductor chip 21 has a circuit 21a formed thereon. The circuit 21a includes a signal transmission/reception circuit and a signal modulation/demodulation circuit. The circuit 21a is electrically connected to the substrate 40 via the bump BP which is connected to an upper surface of the first semiconductor chip 21.

The second semiconductor chip 22 has a circuit 22a formed thereon. The circuit 22a includes a signal transmission/reception circuit and a modulation/demodulation circuit. The circuit 22a is electrically connected to the substrate 40 via the bump BP which is connected to a lower surface of the second semiconductor chip 22.

The plurality of first terminals 11 and the plurality of second terminals 12 are each a plate-shaped metal member extending along the XY plane. The plurality of first terminals 11 and the plurality of second terminals 12 are each connected to the substrate 40 at upper surfaces thereof. The plurality of first terminals 11 and the plurality of second terminals 12 are made of a single plate material. The plurality of first terminals 11 and the plurality of second terminals 12 are each separated from each other by cutting off intermediate portions thereof after they are connected to the substrate 40.

As shown in FIG. 1, the solder portions SD for connecting the first terminals 11 to the substrate 40 and the solder portions SD for connecting the second terminals 12 to the substrate 40 are disposed at ends of the substrate 40 on an opposite side thereto in the X-axis direction. The solder portions SD for connecting the first terminals 11 to the substrate 40 and the solder portions SD for connecting the second terminals 12 to the substrate 40 are disposed at positions different from those of the first semiconductor chip 21 and the second semiconductor chip 22 when viewed in the thickness direction (Z-axis direction) of the substrate 40.

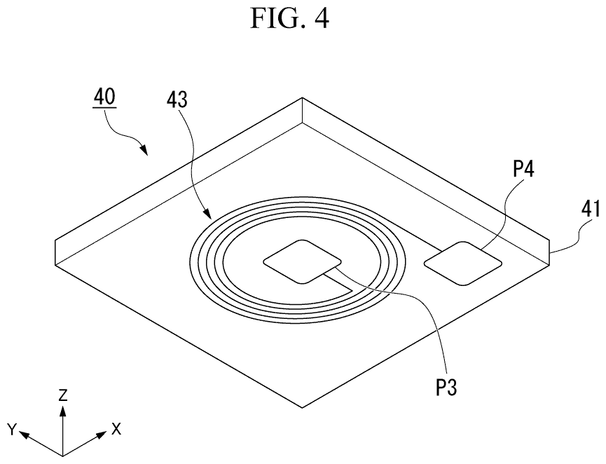

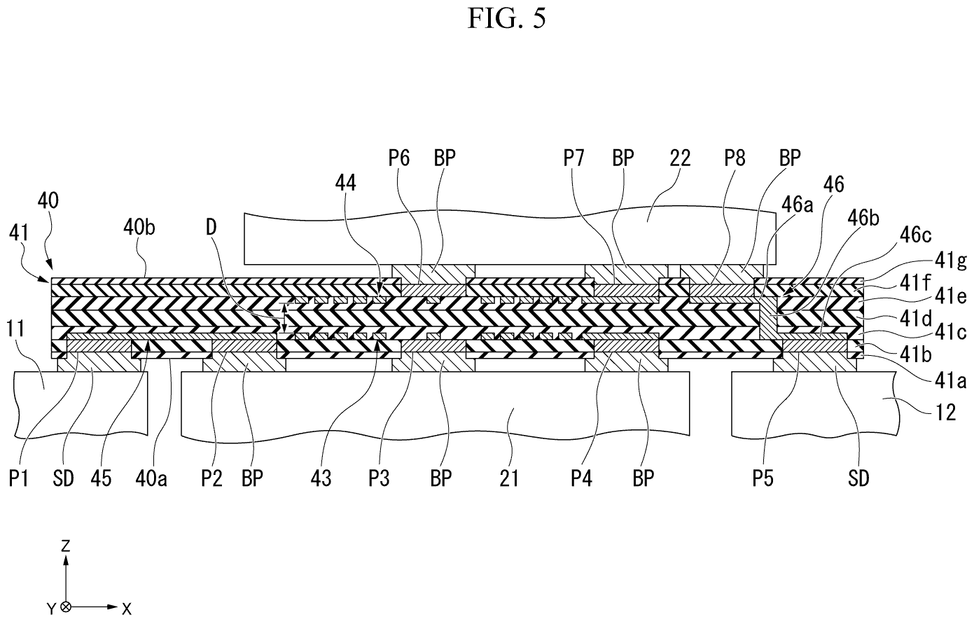

FIG. 3 is a perspective view of the substrate 40 in the embodiment when viewed diagonally from above. FIG. 4 is a perspective view of the substrate 40 in the embodiment when viewed diagonally from below. FIG. 5 is a cross-sectional view of the substrate 40. In FIG. 3 and FIG. 4, in order to make the constitutions of the first coil 43 and the second coil 44 easier to understand, the insulation layer covering the first coil 43 and the second coil 44 is shown transparently. In addition, in FIG. 5, the insulating adhesives 31 and 32 which fix the substrate 40 to the first semiconductor chip 21 and the second semiconductor chip 22 are omitted from the illustration.

As shown in FIGS. 3 and 4, the substrate 40 in the embodiment is formed of a single substrate 41. The substrate 41 in the embodiment is a flexible substrate. However, the substrate 41 may be a rigid substrate. Furthermore, the substrate 41 may be a rigid-flexible substrate. A shape of the substrate 41 may be, for example, rectangular, but is not limited to rectangular and may be any shape.

As shown in FIG. 5, the first coil 43, the second coil 44, a first wiring 45, a second wiring 46, and a plurality of pads P1, P2, P3, P4, P5, P6, P7, and P8 are provided inside the substrate 41. The first coil 43, the second coil 44, the first wiring 45, the second wiring 46, and the pads P1, P2, P3, P4, P5, P6, P7, and P8 are formed, for example, of a copper foil or through copper plating and are conductive.

An exterior shape of the substrate 41 is formed by laminating a plurality of insulation layers 41a, 41b, 41c, 41d, 41e, 41f, and 41g. The plurality of insulation layers 41a, 41b, 41c, 41d, 41e, 41f, and 41g are arranged from the lower side to the upper side in the following order: a first insulation layer 41a, a second insulation layer 41b, a third insulation layer 41c, a fourth insulation layer 41d, a fifth insulation layer 41e, a sixth insulation layer 41f, and a seventh insulation layer 41g.

Among the plurality of pads P1, P2, P3, P4, P5, P6, P7, and P8, the first pad P1, the second pad P2, the third pad P3, the fourth pad P4, and the fifth pad P5 (hereinafter referred to as “first to fifth pads P1, P2, P3, P4, and P5”) are provided inside the second insulation layer 41b and the sixth pad P6, the seventh pad P7, and the eighth pad P8 (hereinafter referred to as “sixth to eighth pads P6, P7, and P8”) are provided inside the sixth insulation layer 41f.

Portions of the first insulation layer 41a that is a layer below the second insulation layer 41b in which the first insulation layer 41a and the first to fifth pads P1, P2, P3, P4, and P5 overlap when viewed in the thickness direction (Z-axis direction) are removed. Thus, the first to fifth pads P1, P2, P3, P4, and P5 are exposed on a lower side of the substrate 40. The first pad P1 is electrically connected to the first terminal 11 via the solder SD. Similarly, the fifth pad P5 is electrically connected to the second terminal 12 via the solder SD. The second pad P2, the third pad P3, and the fourth pad P4 are electrically connected to the first semiconductor chip 21 via the bumps BP.

As shown in FIG. 4, the third pad P3 is electrically connected to a central end of the first coil 43. The fourth pad P4 is electrically connected to an outer circumferential end of the first coil 43. The third pad P3 and the fourth pad P4 have, for example, a rectangular shape with rounded corners when viewed in the thickness direction (Z-axis direction). However, shapes of the third pad P3 and the fourth pad P4 are not limited to this.

As shown in FIG. 5, portions of the seventh insulation layer 41g that is a layer above the sixth insulation layer 41f in which the seventh insulation layer 41g and the sixth to eighth pads P6, P7, and P8 overlap are removed when viewed in the thickness direction (Z-axis direction). Thus, the sixth to eighth pads P6, P7, and P8 are exposed on an upper side of the substrate 40. The sixth to eighth pads P6, P7, and P8 are each electrically connected to the second semiconductor chip 22 via the bumps BP.

As shown in FIG. 3, the sixth pad P6 is electrically connected to a central end of the second coil 44. The seventh pad P7 is electrically connected to an outer circumferential end of the second coil 44. The sixth pad P6 and the seventh pad P7 may have a shape and a size, for example, different from those of the third pad P3 and the fourth pad P4 when viewed in the thickness direction (Z-axis direction). More specifically, when the third pad P3 and the fourth pad P4 each have a rectangular shape, the sixth pad P6 and the seventh pad P7 each may have, for example, a circular shape and may be larger than each of the third pad P3 and the fourth pad P4.

The third pad P3 and the sixth pad P6 are provided at positions in which they overlap each other when viewed in the thickness direction (Z-axis direction). The fourth pad P4 and the seventh pad P7 are provided at positions in which they overlap each other when viewed in the thickness direction (Z-axis direction).

As shown in FIG. 3, a dummy pad Pdm may be provided in the substrate 40. The dummy pads Pdm are provided inside the sixth insulation layer 41f, for example, as in the sixth to eighth pads P6, P7, and P8. Furthermore, the dummy pads Pdm may be provided in the same layer as the first to fifth pads P1, P2, P3, P4, and P5.

The dummy pad Pdm is disposed, for example, at a position in which it is symmetrical to the seventh pad P7 using the sixth pad P6 as a center thereof when the substrate 40 is viewed from the thickness direction (Z-axis direction). A position and a size of the dummy pad Pdm can be determined, for example, on the basis of the center of gravity or the like of the substrate 40 to make it easier to keep the substrate 40 horizontal to the XY plane at the time of installing the substrate 40. Furthermore, the substrate 41 may include a plurality of dummy pads Pdm.

As shown in FIG. 5, the first coil 43 is provided in the third insulation layer 41c. In the embodiment, an upper surface of the first coil 43 is located, for example, below an upper surface of the third insulation layer 41c. However, the upper surface of the first coil 43 may be flush with the upper surface of the third insulation layer 41c. A lower portion of the first coil 43 may be subjected to a plating process. Furthermore, the first coil 43 may be formed of, for example, two or more layers of copper foil.

As shown in FIG. 4, when the substrate 40 is viewed in the thickness direction (Z-axis direction), the first coil 43 has a spirally wound shape and has a predetermined inductance. The first coil 43 is also called a primary coil. The first coil 43 serves as a path for an electrical signal between the bump BP connected to the third pad P3 and the bump BP connected to the fourth pad P4.

As shown in FIG. 5, the second coil 44 is disposed in the fifth insulation layer 41e. In the embodiment, a lower surface of the second coil 44 is located, for example, above a lower surface of the fifth insulation layer 41e. However, the lower surface of the second coil 44 may be flush with the lower surface of the fifth insulation layer 41e. An upper portion of the second coil 44 may be subjected to a plating process. Furthermore, the second coil 44 may be formed of, for example, two or more layers of copper foil.

As shown in FIG. 3, when the substrate 40 is viewed in the thickness direction (Z-axis direction), the second coil 44 has a spirally wound shape and has a predetermined inductance. The second coil 44 is also called a secondary coil. The second coil 44 serves as a path for an electrical signal between the bump BP connected to the sixth pad P6 and the bump BP connected to the seventh pad P7.

With the above-described constitution, the substrate 40 in the embodiment includes an insulation layer 41d and a pair of coils 43 and 44 which are opposite to each other in the thickness direction (Z-axis direction) via the insulation layer 41d. That is to say, the first coil 43 and the second coil 44 are disposed opposite to each other and spaced apart from each other in the thickness direction (Z-axis direction).

In the embodiment, a part of the third insulation layer 41c, the fourth insulation layer 41d, and a part of the fifth insulation layer 41e are disposed between the first coil 43 and the second coil 44.

It is preferable that a thickness D of the insulation layers 41c, 41d, and 41e disposed between the first coil 43 and the second coil 44 be 25 μm or more. As a material which constitutes the insulation layers 41c, 41d, and 41e disposed between the first coil 43 and the second coil 44, generally, a material such as a polyimide having a withstand voltage of 100 kV/mm or more is used. In this case, for this reason, by setting the thickness D to 25 μm or more, a withstand voltage between the first coil 43 and the second coil 44 can be set to 2.5 kV or more. Furthermore, it is preferable that the thickness D of the insulation layers 41c, 41d, and 41e disposed between the first coil 43 and the second coil 44 be 100 μm or less. By setting the thickness D to 100 μm or less, the first coil 43 and the second coil 44 can be arranged close to each other and the transmission efficiency of the electrical signal between the first coil 43 and the second coil 44 can be improved. For the same reason, the thickness D is more preferably 50 μm or less.

Although the insulation layer disposed between the pair of coils 43 and 44 is composed of a plurality of layers (insulation layers 41c, 41d, and 41e) in the embodiment, the insulation layer disposed between the pair of coils 43 and 44 may be a single layer. For example, when the upper surface of the first coil 43 and the upper surface of the third insulation layer 41c are flush with each other and the lower surface of the second coil 44 and the lower surface of the fifth insulation layer 41e are flush with each other, the insulation layer disposed between the pair of coils 43 and 44 is a single layer (the fourth insulation layer 41d). In this case, the thickness D of the insulation layer disposed between the pair of coils 43 and 44 coincides with the thickness of the fourth insulation layer 41d.

As shown in FIG. 5, the first wiring 45 is provided in the third insulation layer 41c. In the embodiment, the first wiring 45 is disposed in the same layer as the first coil 43. However, the first wiring 45 may be disposed in a layer different from that of the first coil 43.

One end portion of the first wiring 45 is connected to the first pad P1 and the other end portion of the first wiring 45 is connected to the second pad P2. As described above, the first pad P1 is connected to the first terminal 11 via the solder SD. Furthermore, the second pad P2 is connected to the first semiconductor chip 21 via the bump BP. Therefore, the first wiring portion 45 electrically connects the first terminals 11 and the first semiconductor chip 21 so that they are bridged.

The second wiring 46 has a first portion 46a, a second portion 46b, and a third portion 46c. The first portion 46a is disposed in the fifth insulation layer 41e. In the embodiment, the first portion 46a is disposed in the same layer as the second coil 44. However, the first portion 46a may be disposed in a layer different from that of the second coil 44. One end portion of the first portion 46a is connected to the eighth pad P8. Furthermore, the other end portion of the first portion 46a is connected to the second portion 46b. The second portion 46b passes through the third insulation layer 41c, the fourth insulation layer 41d, and the fifth insulation layer 41e.

The second portion 46b is formed, for example, by subjecting an inner surface of a through hole to copper plating. An upper end portion of the second portion 46b is connected to the first portion 46a. A lower end portion of the second portion 46b is connected to the third portion 46c.

The third portion 46c is provided in the third insulation layer 41c. In the embodiment, the third portion 46c is disposed in the same layer as the first coil 43 and the first wiring 45. However, the third 46c may be disposed in a layer different from that of the first coil 43 and the first wiring portion 45. One end portion of the third portion 46c is connected to the second portion 46b. Furthermore, the other end portion of the third portion 46c is connected to the fifth pad P5.

Therefore, one end portion of the second wiring 46 is connected to the eighth pad P8 and the other end portion of the second wiring 46 is connected to the fifth pad P5. As described above, the eighth pad P8 is connected to the second semiconductor chip 22 via the bump BP. Furthermore, the fifth pad P5 is connected to the second terminal 12 via the solder SD. Therefore, the second wiring portion 46 electrically connects the second semiconductor chip 22 and the second terminals 12 so they are bridged.

In the substrate 40, the first coil 43, the first wiring 45, and the third portion 46c of the second wiring 46 are formed in the same layer. Similarly, in the substrate 40, the second coil 44 and the first portion 46a of the second wiring 46 are disposed in the same layer. According to the embodiment, conductive metal patterns having different functions are disposed in the same layer. Thus, in comparison with the case in which conductive metal patterns having different functions are arranged on different layers, a thickness dimension of the substrate 40 can be reduced. Furthermore, according to the embodiment, the number of layers of the substrate 41 which constitutes the substrate 40 can be reduced, making it possible to produce the substrate 40 inexpensively.

In the substrate 41, conductive metal patterns having different functions may be disposed on different layers. In this case, by causing the wiring and the coils to partially overlap when the substrate 40 is viewed from the thickness direction (Z-axis direction), it becomes easier to reduce the dimensions of the isolator 10 when viewed in the thickness direction.

An electrical signal path to the isolator 10 will be explained below. An electrical signal input from the first terminals 11 is input to the first semiconductor chip 21 via the solders SD, the first pad P1, the first wiring 45 of the substrate 40, the second pad P2, and the bump BP. This electrical signal is input from the circuit of the first semiconductor chip 21 through the bumps BP and the pads P3 and P4 to the first coil 43 of the substrate 40.

The first coil 43 converts the input electrical signal into magnetic energy. The second coil 44 receives the magnetic energy converted using the first coil 43 and converts it back into electrical energy. The isolator 10 insulates the first semiconductor chip 21 connected to the first coil 43 from the second semiconductor chip 22 connected to the second coil 44 by undergoing conversion into magnetic energy between the first coil 43 and the second coil 44.

An electrical signal flowing through the second coil 44 is input to the second semiconductor chip 22 via the pads P6 and P7 and the bump BP. This electrical signal flows from a circuit of the second semiconductor chip 22 to the second terminal 12 via the solder SD, the second wiring 46 of the substrate 40, the fifth pad P5, and the solder SD.

In this way, in the isolator 10 in the embodiment, an electrical signal input from the first terminals 11 passes through the substrate 40 and reaches the first semiconductor chip 21. Furthermore, an electrical signal from a circuit of the first semiconductor chip 21 flows to the circuit of the second semiconductor chip 22 via the pair of coils 43 and 44 of the substrate 40. Moreover, the electrical signal flowing through the circuit of the second semiconductor chip 22 passes through the substrate 40 and is output from the second terminal 12.

The isolator 10 in the embodiment includes the substrate 40, the first semiconductor chip 21, and the second semiconductor chip 22. The substrate 40 has insulation layers 41c, 41d, and 41e and the pair of coils 43 and 44 which are opposite to each other in the thickness direction via the insulation layers 41c, 41d, and 41e. The first semiconductor chip 21 is disposed to face one surface (the lower surface 40a) of the substrate 40. The first semiconductor chip 21 is connected to one of the pair of coils 43 and 44 (the first coil 43). The second semiconductor chip 22 is disposed to face the other surface (the upper surface 40b) of the substrate 40. The second semiconductor chip 22 is connected to the other of the pair of coils 43 and 44 (the second coil 44).

According to the embodiment, the first semiconductor chip 21 and the second semiconductor chip 22 are laminated in the upward/downward direction on the substrate 40 which has a pair of coils 43 and 44 and functions as an isolator module. For this reason, the substrate 40, the first semiconductor chip 21, and the second semiconductor chip 22 can be disposed so that they overlap each other when the isolator 10 is viewed from the thickness direction (Z-axis direction). As a result, the dimension of the isolator 10 in the thickness direction (Z-axis direction) can be reduced. In other words, the dimension of the isolator 10 in the X-axis direction or the Y-axis direction can be reduced.

Also, according to the embodiment, an isolator module which is formed of the pair of coils 43 and 44 and the insulation layers 41c, 41d, and 41e positioned between the pair of coils 43 and 44 is formed inside the substrate 40. For this reason, in comparison with the case in which the isolator module is formed inside a semiconductor chip, it is easier to adjust the thickness D of the insulation layers 41c, 41d, and 41e and it is easier to improve the insulating performance of the isolator module. In addition, by forming the isolator module in the substrate 40, the isolator 10 can be produced inexpensively.

Also, according to the embodiment, the first semiconductor chip 21 and the second semiconductor chip 22 are laminated on the substrate 40 in the thickness direction (Z-axis direction). For this reason, the first semiconductor chip 21 and the second semiconductor chip 22 can be electrically connected to the substrate 40 through flip chip bonding. According to the embodiment, it is possible to omit a connection step through wire bonding from a production step of the isolator 10 and it is possible to produce the isolator 10 at low cost. In addition, connections performed through flip chip bonding are more reliable than connections performed through wire bonding. According to the embodiment, it is possible to provide the isolator 10 having high reliability.

The isolator 10 in the embodiment has the first terminal 11. The first terminal 11 is connected to the substrate 40. The substrate 40 has the first wiring portion 45. The first wiring portion 45 electrically connects the first terminals 11 and the first semiconductor chip 21.

According to this constitution, the first terminals 11 and the first semiconductor chip 21 can be connected via the first wiring portion 45 of the substrate 40 without being directly connected to each other. For this reason, there is no need to connect the first semiconductor chip 21 and the first terminals 11 through wire bonding and an inexpensive and highly reliable isolator 10 can be provided.

The isolator 10 in the embodiment includes the second terminal 12. The second terminal 12 is connected to the substrate 40. The substrate 40 has the second wiring portion 46. The second wiring portions 46 electrically connect the second terminal 12 and the second semiconductor chip 22. The first terminal 11 and the second terminal 12 are both disposed to face one surface of the substrate 40 (the lower surface 40a).

According to this constitution, the second terminal 12 and the second semiconductor chip 22 can be connected via the second wiring portion 46 of the substrate 40 without being directly connected to each other. For this reason, there is no need to connect the second semiconductor chip 22 and the second terminal 12 through wire bonding and an inexpensive and highly reliable isolator 10 can be provided. In addition, according to the embodiment, the first terminal 11 and the second terminal 12 are disposed on the same side of the substrate 40. For this reason, it is possible to simultaneously connect the first terminal 11 and the second terminal 12 to the substrate 40 from the same direction and it is easy to simplify the production step of the isolator 10.

In the isolator 10 in the embodiment, the thickness D of the insulation layers 41c, 41d, and 41e disposed between the pair of coils 43 and 44 is 25 μm or more. According to this constitution, a sufficient withstand voltage between the coils 43 and 44 can be ensured, thereby providing the isolator 10 having high reliability.

In the isolator 10 in the embodiment, it is preferable that at least a part of the substrate 40 be a flexible substrate. In the flexible substrate, it is easy to make the thickness D of the insulation layers 41c, 41d, and 41e between the coils 43 and 44 thin. More specifically, it is easy to set the thickness D of the insulation layers 41c, 41d, and 41e to a thickness of 25 μm or more and 50 μm or less. For this reason, by forming a region of the substrate 40 in which the pair of coils 43 and 44 are provided from a flexible substrate, the insulation layers 41c, 41d, and 41e between the pair of coils 43, 44 can be made thin. As a result, it is possible to dispose the pair of coils 43 and 44 close to each other, thereby improving the transmission efficiency of the isolator 10.

In the isolator 10 in the embodiment, it is preferable that at least a part of the substrate 40 be a rigid substrate. Rigid substrates can be less expensive to produce than flexible substrates. For this reason, by making at least a part of the substrate 40 have a rigid substrate, it is possible to produce a substrate more inexpensively than when the entire substrate is formed of a flexible substrate.

In the isolator 10 in the embodiment, the substrate is composed of a single substrate 41 on which one and the other of the pair of coils 43 and 44 are formed in different layers.

According to this constitution, the production step can be provided less complicated than in the case in which a substrate is formed by bonding a substrate including a first coil and a substrate including a second coil (a modified example which will be described later). More specifically, when a substrate including a first coil and a substrate including a second coil are bonded together to form a substrate, the occurrence of misalignment of the first coil and the second coil during a bonding step may cause degradation of the characteristics of the isolator module in some cases. For this reason, the production step may become complicated to suppress the occurrence of misalignment between the first coil and the second coil. According to the embodiment, the first coil 43 and the second coil 44 are both provided in the same substrate 41 so that the coils 43 and 44 are less likely to be misaligned in a plane perpendicular to the thickness direction, thereby preventing deterioration of characteristics while also preventing the production step from becoming complicated.

### Modified Example

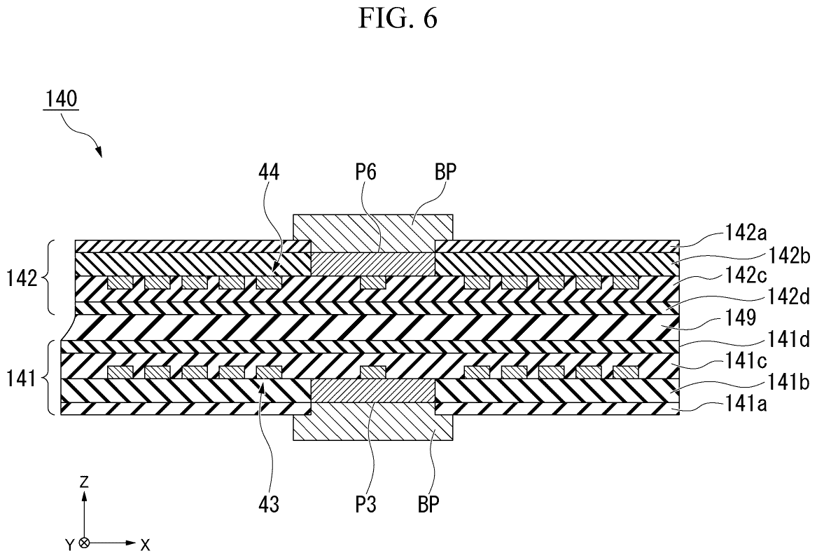

A substrate 140 in a modified example which can be adopted in the embodiment will be described below with reference to FIG. 6. The substrate 140 in the modified example differs from the above-described embodiment mainly in that the substrate 140 is formed by bonding a plurality of substrates 141 and 142 in a thickness direction. The constituent elements having the same aspects as those in the above-described embodiment are denoted by the same reference numerals and description thereof will be omitted.

As in the substrate 40 of the above-described embodiment, a substrate 140 in the modified example functions as an isolator module disposed between a first semiconductor chip 21 and a second semiconductor chip 22 in an isolator 10. In FIG. 6, a plurality of pads provided on the substrate 140 are omitted from the illustration.

The substrate 40 in the modified example includes an adhesive layer (insulation layer) 149, a first substrate 141, and a second substrate 142. In the modified example, the first substrate 141 and the second substrate 142 are both flexible substrates. However, either or both of the first substrate 141 and the second substrate 142 may be rigid or rigid flexible substrates.

A first coil 43 is provided inside the first substrate 141. An exterior shape of the first substrate 141 is formed by laminating a plurality of insulation layers 141a, 141b, 141c, and 141d. The first coil 43 is embedded inside the insulation layer 141c. Although a part of the illustration is omitted, inside the first substrate 141, as in the embodiment described above, the first wiring 45, a part of the second wiring 46, and a plurality of pads P1, P2, P3, P4, and P5 are provided.

The second coil 44 is provided inside the second substrate 142. An exterior shape of the second substrate 142 is formed by laminating a plurality of insulation layers 142a, 142b, 142c, and 142d. The second coil 44 is embedded inside the insulation layer 142c. Although a part of the illustration is omitted, inside the second substrate 142, as in the embodiment described above, the first wiring 45, a part of the second wiring 46, and a plurality of pads P5, P6, P7, and P8 are provided.

The adhesive layer 149 is made of an insulating adhesive agent. The adhesive layer 149 is disposed between the first substrate 141 and the second substrate 142. The adhesive layer 149 bonds the insulation layer 141d that is the uppermost layer of the first substrate 141 to the insulation layer 142d that is the lowermost layer of the second substrate 142. Thus, the adhesive layer 149 integrates the first substrate 141 and the second substrate 142 together.

The substrate 140 in the modified example includes the first substrate 141 and the second substrate 142. The first substrate 141 and the second substrate 142 are laminated in the thickness direction (Z-axis direction) via an adhesive layer (insulation layer) 149. In the first substrate 141, one of the pair of coils 43 and 44 (the first coil 43) is formed. In the second substrate 142, the other of the pair of coils 43 and 44 (the second coil 44) is formed.

According to the modified example, the first substrate 141 including the first coil 43 and the second substrate 142 including the second coil 44 are bonded together to form the substrate 140. For this reason, a thickness of the adhesive layer 149 can be easily controlled at the time of bonding. Thus, the withstand voltage and the transmission efficiency of the isolator 10 can be adjusted.

Also, according to the modified example, a step in which the first substrate 141 is connected to the first semiconductor chip 21, the second substrate 142 is connected to the second semiconductor chip 22, and then the first substrate 141 and the second substrate 142 are bonded together can be adopted. For this reason, a step of flip chip bonding between the first substrate 141 and the first semiconductor chip 21 and a step of flip chip bonding between the second substrate 142 and the second semiconductor chip 22 can be simplified.

According to at least one of the embodiments described above, by providing the substrate 40 having the pair of coils which are opposite to each other via the insulation layer and the first semiconductor chip 21 and the second semiconductor chip 22 having the substrate 40 disposed therebetween on both sides in the thickness direction (Z-axis direction), it is possible to provide the isolator 10 which can be made smaller in planar dimensions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An isolator comprising:
a substrate which has an insulation layer and a pair of coils which are opposite to each other in a thickness direction via the insulation layer;
a first chip which is disposed to face one surface of the substrate and connected to one of the pair of coils; and
a second chip which is disposed to face the other surface of the substrate and connected to the other of the pair of coils.

2. The isolator according to claim 1, comprising:
a first terminal which is connected to the substrate,
wherein the substrate has a first wiring portion which electrically connects the first terminal and the first chip.

3. The isolator according to claim 2, comprising:
a second terminal which is connected to the substrate,
wherein the substrate has a second wiring portion which electrically connects the second terminal and the second chip, and
the first terminal and the second terminal are both disposed to face one surface of the substrate.

4. The isolator according to claim 1, wherein a thickness of the insulation layer is 25 μm or more.

5. The isolator according to claim 1, wherein at least a part of the substrate is a flexible substrate.

6. The isolator according to claim 1, wherein at least a part of the substrate is a rigid substrate.

7. The isolator according to claim 1, wherein the substrate is composed of a single substrate on which one and the other of the pair of coils are formed in different layers.

8. The isolator according to claim 1, wherein the substrate has a first substrate and a second substrate which are laminated in the thickness direction via the insulation layer,
the first substrate has one of the pair of coils formed thereon, and
the second substrate has the other of the pair of coils formed thereon.
